(19) United States
(12) Patent Application Publication
(10) Pub. No.: US 2022/0090769 A1
(43) Pub. Date: Mar. 24, 2022

(54) LED LIGHTING, CONNECTING COPPER SHEET AND CONTINUOUS CONNECTING COPPER SHEET

(71) Applicant: Guang Zhou Ting Shen Electric Co., LTD, Guangdong (CN)

(72) Inventor: CHIA-CHUN WANG, Guangdong (CN)

(73) Assignee: Guang Zhou Ting Shen Electric Co., LTD, Guangdong (CN)

(21) Appl. No.: 17/037,709

(22) Filed: Sep. 30, 2020

(30) Foreign Application Priority Data
Sep. 24, 2020 (CN) 202022124599.3

(51) Int. Cl. F21V 23/00; H01L 33/62

(52) U.S. Cl. CPC F21V 23/001; F21Y 2115/10; H01L 33/62

(57) ABSTRACT

An LED lighting includes an LED lamp, a connecting wire, and a connecting copper sheet used to connect the LED lamp and the connecting wire. The connecting copper sheet includes a first fixing sheet used to connect with the pin of the LED lamp, a second fixing sheet used to connect with the core wire of the connecting wire, a third fixing sheet used to connect with the sheath of the connecting wire, and a copper strip for connecting the first fixing sheet and the second fixing sheet. The length of the third fixing sheet is longer than that of the second fixing sheet. The width of the third fixing sheet is shorter than that of the second fixing sheet. The third fixing sheet is concatenated with the second fixing sheet, and the connecting copper sheet is sheathed with an insulating sleeve.

### CROSS-REFERENCE TO RELATED APPLICATION

This application claims the priority benefit of China application serial no. 202022124599.3, filed on Sep. 24, 2020. The entirety of the above-mentioned patent application is hereby incorporated by reference herein and made a part of this specification.

### BACKGROUND

### Technical Field

This application relates to the field of LED, particularly to an LED lighting and a connecting copper sheet.

### Description of Related Art

At present, there are two connection methods in the LED production industry: 1. The pins of an LED lamp are plugged into a soft core shell; a copper terminal connects with a connecting wire by pressure riveting, and then a soft head shell is assembled; finally, the soft core shell is plugged into the soft head shell to assemble. 2. An LED lamp and wire are welded, and the welded part is sheathed with a shrink film. The existing connection methods have the following defects: (1) The connection between the LED lamp and the wire requires assembly through a dedicated connector, which leads to a cumbersome manufacturing process, so the LED assembly consumes a lot of manpower and man-hours. (2) The copper terminal that connects with the connecting wire by pressure riveting consumes more copper material, resulting in higher product material costs. (3) The LED lamp-wire welding process requires qualified and skilled welding operators to avoid damage to the LED lamp due to high-temperature during welding. (4) LED soldering operations often produce tin tips. These tips will pierce the insulative shrink film in the sheathing process, which may cause the product to suffer electric shock during use. (5) In the fabrication process, a large number of inspectors are required to check LED reversal, empty soldering, poor contact, damaged insulation and other steps.

### SUMMARY

In order to solve the above-mentioned technical problems ‘ the present invention provides an LED lighting and a connecting copper sheet’ which can optimize the fabrication process, reduce the assembly processes and the inspection staff stations, improve the first pass yield of products, and reduce the product manufacturing costs.

To solve the above mentioned technical problems, one technical solution of the present invention is as follows: An LED lighting includes an LED lamp, a connecting wire, and a connecting copper sheet used to connect the LED lamp and the connecting wire. The said connecting copper sheet comprises a first fixing sheet used to connect with the pin of the LED lamp, a second fixing sheet used to connect with the wire core of the connecting wire, a third fixing sheet used to connect with the sheath of the connecting wire, and a copper strip for connecting the first fixing sheet and the second fixing sheet. The length of the third fixing sheet is longer than that of the second fixing sheet. The width of the third fixing sheet is shorter than that of the second fixing sheet. The third fixing sheet is concatenated with the second fixing sheet. The connecting copper sheet is sheathed with an insulating sleeve. The first fixing sheet is formed into the C shape and the shape is similar to that of the pin, which facilitates the insertion and positioning of the pin, and realizes a reliable electrical connection with the LED lamp pin after riveting. The second fixing sheet is formed into the V shape and can clamp the wire core of the connecting wire after riveting to ensure the electrical connection between the connecting copper sheet and the connecting wire. The third fixing sheet is formed into the V shape and can clamp the sheath of the connecting wire after riveting to ensure the mechanical connection between the connecting copper sheet and the connecting wire, and to prevent the wire core of the connecting wire from being separated from the connecting copper sheet.

As an improvement, pits formed by pressure riveting are provided on the surface of the first fixing sheet.

As an improvement, the insulating sleeve is a heat-shrinkable sleeve or a plastic sleeve.

As an improvement, the connecting copper sheet is formed by integrated stamping and bending.

In order to solve the above technical problems, another technical solution of the present invention is as follows: A connecting copper sheet comprises a first fixing sheet, a second fixing sheet, a third fixing sheet, and a copper strip for connecting the first fixing sheet and the second fixing sheet. The length of the third fixing sheet is longer than that of the second fixing sheet. The width of the third fixing sheet is shorter than that of the second fixing sheet. The third fixing sheet is concatenated with the second fixing sheet. The first fixing sheet is C-shaped, and the second fixing sheet and the third fixing sheet are V-shaped. The connecting copper sheet of the present technical solution is used for the connection between the leading-out wire of a connector and the pin of the LED lamp.

In order to solve the above technical problems, another technical solution of the present invention is as follows: A continuous connecting copper sheet comprises a number of connecting copper sheets that are parallelly arranged. The said connecting copper sheet comprises a first fixing sheet, a second fixing sheet, a third fixing sheet, and a copper strip for connecting the first fixing sheet and the second fixing sheet. The length of the third fixing sheet is longer than that of the second fixing sheet. The width of the third fixing sheet is shorter than that of the second fixing sheet. The third fixing sheet is concatenated with the second fixing sheet. The first fixing sheet is C-shaped, and the second fixing sheet and the third fixing sheet are V-shaped. The adjacent connecting copper sheets are concatenated by a copper strip.

In order to solve the above technical problems, another technical solution of the present invention is as follows: An LED lighting includes an LED lamp, a connecting wire, and a connecting copper sheet used to connect the LED lamp and the connecting wire. The said connecting copper sheet comprises a first fixing sheet used to connect with the pin of the LED lamp, a second fixing sheet used to connect with the wire core of the connecting wire, and a third fixing sheet used to connect with the sheath of the connecting wire. The first fixing sheet, the second fixing sheet and the third fixing sheet are concatenated in series. The length of the third fixing sheet is longer than that of the second fixing sheet. The length of the second fixing sheet is longer than that of the first fixing sheet. The width of the third fixing sheet is shorter than that of the second fixing sheet. The width of the second fixing sheet is shorter than that of the first fixing sheet. The said connecting copper sheet is sheathed with an insulating sleeve.

In order to solve the above technical problems, another technical solution of the present invention is as follows: A connecting copper sheet comprises a first fixing sheet, a second fixing sheet, and a third fixing sheet. The first fixing sheet, the second fixing sheet and the third fixing sheet are concatenated in series. The length of the third fixing sheet is longer than that of the second fixing sheet. The length of the second fixing sheet is longer than that of the first fixing sheet. The width of the third fixing sheet is shorter than that of the second fixing sheet. The width of the second fixing sheet is shorter than that of the first fixing sheet. The first fixing sheet, the second fixing sheet and the third fixing sheet are V-shaped, or the first fixing sheet, the second fixing sheet and the third fixing sheet are U-shaped.

In order to solve the above technical problems, another technical solution of the present invention is as follows: A continuous connecting copper sheet comprises a number of connecting copper sheets that are serially arranged. The said connecting copper sheet comprises a first fixing sheet, a second fixing sheet, and a third fixing sheet. The first fixing sheet, the second fixing sheet and the third fixing sheet are concatenated in series. The length of the third fixing sheet is longer than that of the second fixing sheet. The length of the second fixing sheet is longer than that of the first fixing sheet. The width of the third fixing sheet is shorter than that of the second fixing sheet. The width of the second fixing sheet is shorter than that of the first fixing sheet. The first fixing sheet, the second fixing sheet and the third fixing sheet are V-shaped, or the first fixing sheet, the second fixing sheet and the third fixing sheet are U-shaped. The adjacent connecting copper sheets are concatenated by a copper strip.

The advantageous effects of the present invention compared with the prior art are as follows: The first fixing sheet is formed into the C shape and the shape is similar to that of the pin, which facilitates the insertion and positioning of the pin, and realizes a reliable electrical connection with the LED lamp pin after riveting. The second fixing sheet is formed into the V shape and can clamp the wire core of the connecting wire after riveting to ensure the electrical connection between the connecting copper sheet and the connecting wire. The third fixing sheet is formed into the V shape and can clamp the sheath of the connecting wire after riveting to ensure the mechanical connection between the connecting copper sheet and the connecting wire, and to prevent the wire core of the connecting wire from being separated from the connecting copper sheet. Moreover, the application of the present continuous connecting copper sheet can realize the automatic fabrication process and simplify the production process. The first pass yield is exceptionally high. No professional welding positions are required in the process. The test efficiency is improved, and the appearance inspection staff are reduced by about 80%.

### BRIEF DESCRIPTION OF THE DRAWINGS

FIG. 1 is a schematic illustration of the connection between the LED lamp and the connector in embodiment 1.

FIG. 2 is a top view of the connecting copper sheet in embodiment 1.

FIG. 3 is a section view of the connecting copper sheet in embodiment 1.

FIG. 4 is a side view of the connecting copper sheet in embodiment 1.

FIG. 5 is a schematic illustration of the continuous connecting copper sheet in embodiment 1.

FIG. 6 is a side view of the connecting copper sheet in embodiment 2.

FIG. 7 is a schematic illustration of the continuous connecting copper sheet in embodiment 2.

### DESCRIPTION OF THE EMBODIMENTS

In conjunction with drawings, further illustration on the present invention will be given in the following.

### Embodiment 1

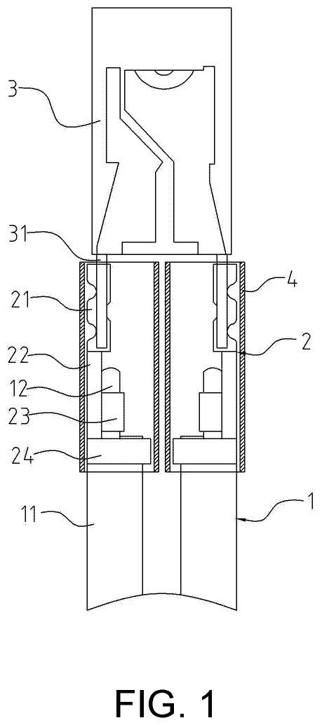

As shown in FIG. 1, an LED lighting includes an LED lamp 3, a connecting wire 1, and a connecting copper sheet 2 used to connect the LED lamp 3 and the connecting wire 1.

As shown in FIG. 1, the LED lamp 3 can be an LED light bar, an LED bulb or a simple light-emitting diode. The LED lamp 3 has two leading-out pins: positive and negative. The pins are electrically connected through the connecting wire 1 and the external power supply charges LED lamp 3 through the connecting wire 1.

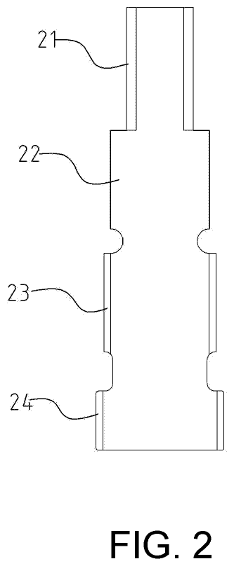

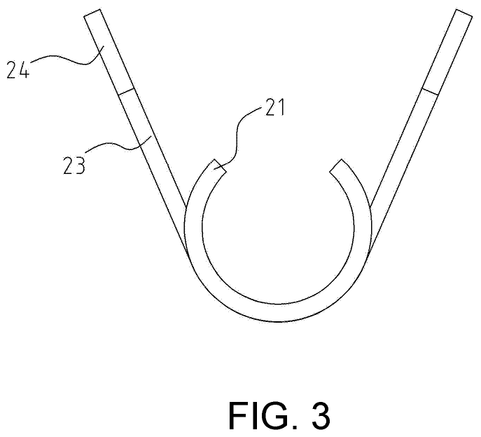

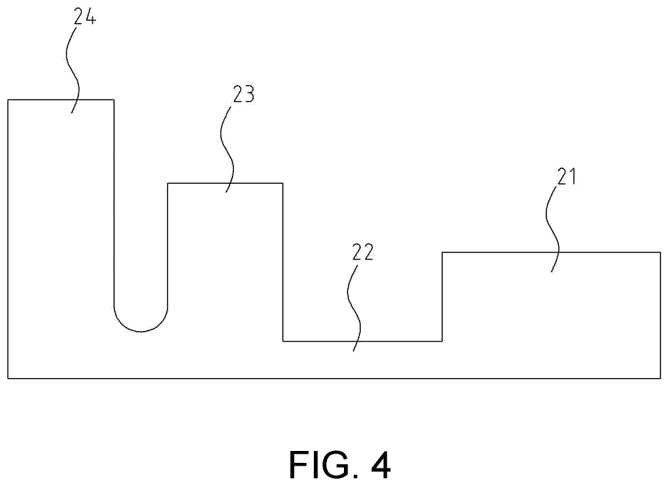

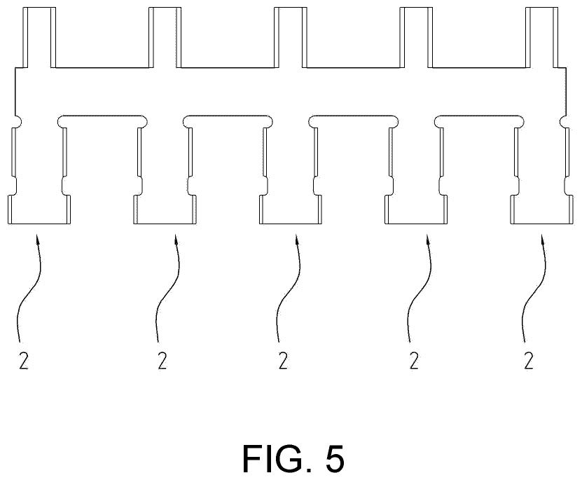

As shown in FIGS. 2 to 4, the connecting copper sheet 2 includes a first fixing sheet 21 used to connect with the pin 31 of the LED lamp, the second fixing sheet 23 used to connect with the wire core 12 of the connecting wire 1, the third fixing sheet 24 used to connect with the sheath 11 of the connecting wire 1 and the copper strip 22 for connecting the first fixing sheet 21 and the second fixing sheet 23. The connecting copper sheet 2 is formed by integrated stamping and bending. After forming, the first fixing sheet 21 is C-shaped, and the second fixing sheet 23 and the third fixing sheet 24 are V-shaped. The length of the third fixing sheet 24 is longer than that of the second fixing sheet 23. The width of the third fixing sheet 24 is shorter than that of the second fixing sheet 23. The third fixing sheet 24 and the second fixing sheet 23 are concatenated, and the connection between the two is arc. As shown in FIG. 5, in order to realize large-scale automated production, the connecting copper sheet 2 is continuously produced by a long copper strip to form a continuous connecting copper sheet, that is, the adjacent connecting copper sheets are parallelly concatenated by the copper strip.

In the assembling process, the continuous copper strip 22 is cut and the corresponding fixing sheet is bent. Besides, the continuous connecting copper sheet connects a plurality of LED lamps 3 in series to form lighting decorations such as Christmas lights. Based on the structure of the connecting copper sheet of the present invention, the automatic production of LED lighting decorations can be realized. The connecting copper sheet 2 is sheathed with an insulating sleeve 4, and the insulating sleeve 4 is heat-shrinkable. The heat-shrinkable sleeve can not only protect the connecting copper sheet 2 from the electrical short circuit but also enhance the mechanical connection strength among the connecting copper sheet 2, the pin 31 and the connecting wire 1.

The first fixing sheet 21 of the present invention is formed into the C shape, and the shape is similar to that of the pin 31, which facilitates the insertion and positioning of the pin 31, and realizes a reliable electrical connection with the pin 31 and the connecting wire 1 after riveting. The second fixing sheet 23 is formed into the V shape, and the wire core 12 of the leading-out wire can be clamped to ensure the electrical connection between the connecting copper sheet 2 and the leading-out wire. The third fixing sheet 24 is formed into the V shape. After riveting, the sheath 11 of the connecting wire can be clamped to ensure the mechanical connection between the connecting copper sheet 2 and the connecting wire 1, and to prevent the wire core 12 from being separated from the connecting copper sheet 2.

### Embodiment 2

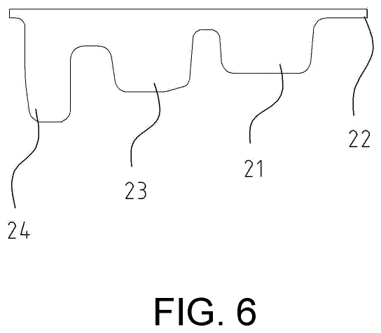

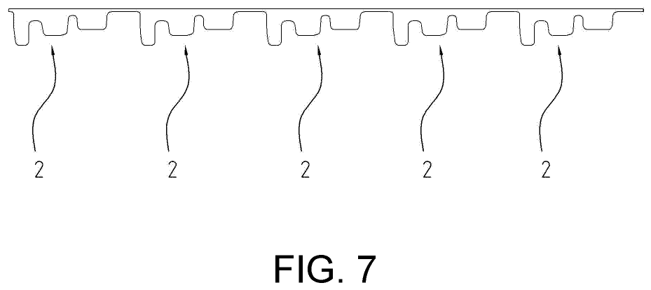

As shown in FIGS. 6 and 7, what is different from Embodiment 1 is that the connecting copper sheet includes the first fixing sheet 21, the second fixing sheet 23 and the third fixing sheet 24. The first fixing sheet 21, the second fixing sheet 23 and the third fixing sheet 24 are concatenated in series. The length of the third fixing sheet 24 is longer than that of the second fixing sheet 23. The length of the second fixing sheet 23 is longer than that of the first fixing sheet 21. The width of the third fixing sheet 24 is shorter than that of the second fixing sheet 23. The width of the second fixing sheet 23 is shorter than that of the first fixing sheet 21. The first fixing sheet 21, the second fixing sheet 23 and the third fixing sheet 24 are all V-shaped or U-shaped. In order to realize large-scale automated production, the connecting copper sheet 2 is continuously produced by a long copper strip to form a continuous connecting copper sheet, that is, the adjacent connecting copper sheets are serially concatenated by the copper strip. In the assembling process, the continuous copper strip is cut and the corresponding fixing sheet is bent.

What is claimed is:

1. An LED lighting, comprising: an LED lamp, a connecting wire, and a connecting copper sheet used to connect the LED lamp and the connecting wire, wherein the connecting copper sheet comprises:
a first fixing sheet used to connect with a pin of the LED lamp;
a second fixing sheet used to connect with a wire core of the connecting wire;
a third fixing sheet used to connect with a sheath of the connecting wire; and
a copper strip for connecting the first fixing sheet and the second fixing sheet,
wherein a length of the third fixing sheet is longer than a length of the second fixing sheet;
a width of the third fixing sheet is shorter than a width of the second fixing sheet;
the third fixing sheet is concatenated with the second fixing sheet; and
the connecting copper sheet is sheathed with an insulating sleeve.

2. The LED lighting according to claim 1, wherein pits formed by pressure riveting are provided on a surface of the first fixing sheet.

3. The LED lighting according to claim 1, wherein the insulating sleeve is a heat-shrinkable sleeve or a plastic sleeve.

4. The LED lighting according to claim 1, wherein the connecting copper sheet is formed by integrated stamping and bending.

5. A connecting copper sheet, comprising:
a first fixing sheet;
a second fixing sheet;
a third fixing sheet; and
a copper strip for connecting the first fixing sheet and the second fixing sheet, wherein
a length of the third fixing sheet is longer than a length of the second fixing sheet;
a width of the third fixing sheet is shorter than a width of the second fixing sheet;
the third fixing sheet is concatenated with the second fixing sheet;
the first fixing sheet is C-shaped, and the second fixing sheet and the third fixing sheet are V-shaped.

6. A continuous connecting copper sheet, comprising: a number of connecting copper sheets parallelly arranged, the connecting copper sheet comprising:
a first fixing sheet;
a second fixing sheet;
a third fixing sheet; and
a copper strip for connecting the first fixing sheet and the second fixing sheet, wherein
a length of the third fixing sheet is longer than a length of the second fixing sheet;
a width of the third fixing sheet is shorter than a width of the second fixing sheet;
the third fixing sheet is concatenated with the second fixing sheet;
the first fixing sheet is C-shaped, and the second fixing sheet and the third fixing sheet are V-shaped; and
the adjacent connecting copper sheets are concatenated by a copper strip.

7. An LED lighting, comprising: an LED lamp, a connecting wire, and a connecting copper sheet used to connect the LED lamp and the connecting wire, wherein the connecting copper sheet comprises:
a first fixing sheet used to connect with a pin of the LED lamp;
a second fixing sheet used to connect with a wire core of the connecting wire; and
a third fixing sheet used to connect with a sheath of the connecting wire,
wherein the first fixing sheet, the second fixing sheet and the third fixing sheet are concatenated in series;
a length of the third fixing sheet is longer than a length of the second fixing sheet;
the length of the second fixing sheet is longer than a length of the first fixing sheet;
a width of the third fixing sheet is shorter than a width of the second fixing sheet;
the width of the second fixing sheet is shorter than a width of the first fixing sheet; and
the connecting copper sheet is sheathed with an insulating sleeve.

8. A connecting copper sheet, comprising:
a first fixing sheet;
a second fixing sheet; and
a third fixing sheet,
wherein the first fixing sheet, the second fixing sheet and the third fixing sheet are concatenated in series;
a length of the third fixing sheet is longer than a length of the second fixing sheet;
the length of the second fixing sheet is longer than a length of the first fixing sheet;
a width of the third fixing sheet is shorter than a width of the second fixing sheet; the width of the second fixing sheet is shorter than a width of the first fixing sheet; and
the first fixing sheet, the second fixing sheet and the third fixing sheet are V-shaped, or the first fixing sheet, the second fixing sheet and the third fixing sheet are U-shaped.

9. A continuous connecting copper sheet, comprising: a number of connecting copper sheets serially arranged, the connecting copper sheet comprising:
a first fixing sheet;
a second fixing sheet; and
a third fixing sheet,
wherein the first fixing sheet, the second fixing sheet and the third fixing sheet are concatenated in series;
a length of the third fixing sheet is longer than a length of the second fixing sheet;
the length of the second fixing sheet is longer than a length of the first fixing sheet;
a width of the third fixing sheet is shorter than a width of the second fixing sheet;
the width of the second fixing sheet is shorter than a width of the first fixing sheet;
the first fixing sheet, the second fixing sheet and the third fixing sheet are V-shaped, or the first fixing sheet, the second fixing sheet and the third fixing sheet are U-shaped; and
the adjacent connecting copper sheets are concatenated by a copper strip.
